(19) United States
(12) Patent Application Publication
(10) Pub. No.: US 2017/0309520 A1
(43) Pub. Date: Oct. 26, 2017

(54) SEMICONDUCTOR DEVICE AND METHOD FOR FABRICATING THE SAME

(71) Applicant: UNITED MICROELECTRONICS CORP., Hsin-Chu City (TW)

(72) Inventors: En-Chiuan Liou, Tainan City (TW); Chih-Wei Yang, Kaohsiung City (TW); Kuan-Ying Lai, Chiayi City (TW)

(21) Appl. No.: 15/158,608

(22) Filed: May 19, 2016

(30) Foreign Application Priority Data
Apr. 25, 2016 (CN) 201610260956.4

(51) Int. Cl. H01L 21/8234; H01L 29/66; H01L 29/423; H01L 29/78; H01L 27/088

(52) U.S. Cl. CPC H01L 21/823456; H01L 29/78; H01L 27/088; H01L 29/42376; H01L 29/66545

(57) ABSTRACT

A method for fabricating semiconductor device is disclosed. First, a substrate is provided, and a first metal gate and a second metal gate are formed on the substrate, in which the first metal gate includes a first work function metal layer, the second metal gate includes a second work function metal layer, the first metal gate and the second metal gate include different size, and the first work function metal layer and the second work function metal layer include different thickness.

### BACKGROUND OF THE INVENTION

### 1. Field of the Invention

The invention relates to a method for fabricating semiconductor device, and more particularly, to a method of fabricating metal gates having different sizes.

### 2. Description of the Prior Art

In current semiconductor industry, polysilicon has been widely used as a gap-filling material for fabricating gate electrode of metal-oxide-semiconductor (MOS) transistors. However, the conventional polysilicon gate also faced problems such as inferior performance due to boron penetration and unavoidable depletion effect which increases equivalent thickness of gate dielectric layer, reduces gate capacitance, and worsens driving force of the devices. In replacing polysilicon gates, work function metals have been developed to serve as a control electrode working in conjunction with high-K gate dielectric layers.

However, in current fabrication of high-k metal gate transistor, voids are often formed during the deposition of work function metal layer for fabricating multi-VT devices and affect the performance of the device substantially. Hence, how to resolve this issue has become an important task in this field.

### SUMMARY OF THE INVENTION

According to a preferred embodiment of the present invention, a method for fabricating semiconductor device is disclosed. First, a substrate is provided, and a first metal gate and a second metal gate are formed on the substrate, in which the first metal gate includes a first work function metal layer, the second metal gate includes a second work function metal layer, the first metal gate and the second metal gate include different size, and the first work function metal layer and the second work function metal layer include different thickness.

According to an embodiment of the present invention, a semiconductor device is disclosed. The semiconductor device includes: a substrate; a first metal gate on the substrate, wherein the first metal gate comprises a first work function metal layer; and a second metal gate on the substrate, in which the second metal gate includes a second work function metal layer, the first metal gate and the second metal gate include different size, and the first work function metal layer and the second work function metal layer include different thickness.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating a semiconductor device according to a preferred embodiment of the present invention.

### DETAILED DESCRIPTION

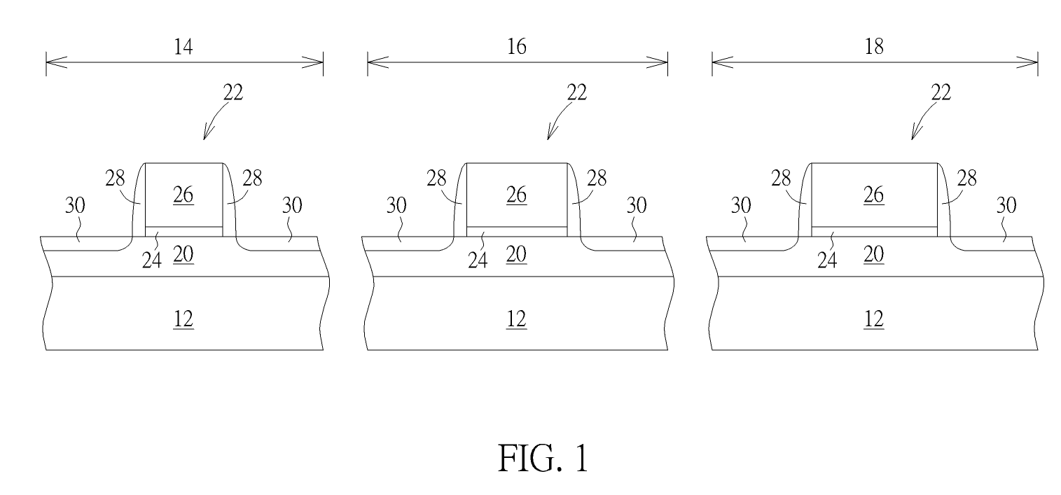

Referring to FIGS. 1-5, FIGS. 1-5 illustrate a method for fabricating a semiconductor device according to a preferred embodiment of the present invention. As shown in FIG. 1, a substrate 12, such as a silicon substrate or silicon-on-insulator (SOI) substrate is provided, and three or more transistor regions, such as regions 14, 16, 18 are defined on the substrate 12. In this embodiment, the three regions 14, 16, 18 are transistor regions sharing same conductive type, such as all being PMOS regions or NMOS regions. Preferably, the three regions 14, 16, 18 are defined to fabricate gate structures having different threshold voltages in the later process. In this embodiment, at least a fin-shaped structure 20 is formed on each of the transistor regions 14, 16, 18, and the bottom of the fin-shaped structure 20 is surrounded by a shallow trench isolation (STI) (not shown) composed of silicon oxide. It should be noted that even though this embodiment pertains to a FinFET process, it would also be desirable to apply the process of this embodiment to a non-planar MOS transistor, which is also within the scope of the present invention.

The fin-shaped structure 20 of this embodiment is preferably obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structure 20 of this embodiment could also be obtained by first forming a patterned mask (not shown) on the substrate, 12, and through an etching process, the pattern of the patterned mask is transferred to the substrate 12 to form the fin-shaped structure 20. Moreover, the formation of the fin-shaped structure 20 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structure 20. These approaches for forming fin-shaped structure 20 are all within the scope of the present invention.

Next, gate structures or dummy gates 22 are formed on the substrate 12. In this embodiment, the formation of the dummy gates 22 could be accomplished by sequentially depositing a gate dielectric layer, a gate material layer, and a selective hard mask on the substrate 12, conducting a pattern transfer process by using a patterned resist (not shown) as mask to remove part of the gate material layer and part of the gate dielectric layer, and then stripping the patterned resist to form dummy gates 22 or gate structures on the fin-shaped structure 20 on regions 14, 16, 18. Each of the dummy gates 22 preferably includes a patterned gate dielectric layer 24 and a patterned material layer 26

It should be noted that the three regions 14, 16, 18 are preferably transistors regions having same conductive type, such as all being PMOS regions or all being NMOS regions, and the regions 14, 16, 18 are defined to fabricate gate structures with different threshold voltages in the later process, it would be desirable to form bottom barrier metal (BBM) and/or work function metal layer having different thickness and/or different number of layers in the regions after the dummy gates are transformed into metal gates. In order to achieve this, it would be desirable to use optical proximity correction (OPC) process to adjust or pre-size the size of the gate trench or gate width so that the gate trench used to form gate having thicker and/or more layers of BBM layer and/or work function layers would become relatively wider than the original gate trench size.

Preferably, the dummy gates 22 on the regions 14, 16, 18 are formed to adapt to transistors having different threshold voltage thereby having different size. For instance, the region 14 is used to prepare standard voltage threshold (SVT) transistor device, hence the dummy gate 22 on this region 14 preferably has the smallest size; the region 16 is used to prepare low voltage threshold (LVT) transistor device, hence the dummy gate 22 on this region 16 preferably has a medium size or slightly larger than the dummy gate 22 on region 14; the region 18 is used to prepare ultra low voltage threshold (ULVT) transistor device, hence the dummy gate 22 on this region 18 has the largest size. It should be noted that the term “size” used in this embodiment specifically refers to that each of the dummy gates 22 having different width and/or length along the channel direction on each of the regions 14, 16, 18 while other parameters such as material or height of the dummy gates 22 are the same.

Next, at least a spacer 28 is formed on the sidewalls of each dummy gate 22, a source/drain region 30 and/or epitaxial layer (not shown) is formed in the fin-shaped structure 20 and/or substrate 12 adjacent to two sides of the spacer 28, and a selective silicide (not shown) is formed on the surface of the source/drain region 30 and/or epitaxial layer. In this embodiment, the spacer 28 could be a single spacer or a composite spacer. For instance, the spacer 28 could further include an offset spacer (not shown) and a main spacer (not shown) , and the spacer 28 could be selected from the group consisting of SiO₂, SiN, SiON, and SiCN. The source/drain region 30 and epitaxial layer could include different dopants or different material depending on the type of transistor being fabricated. For instance, the source/drain region 30 could include p-type or n-type dopants and the epitaxial layer could include SiGe, SiC, or SiP.

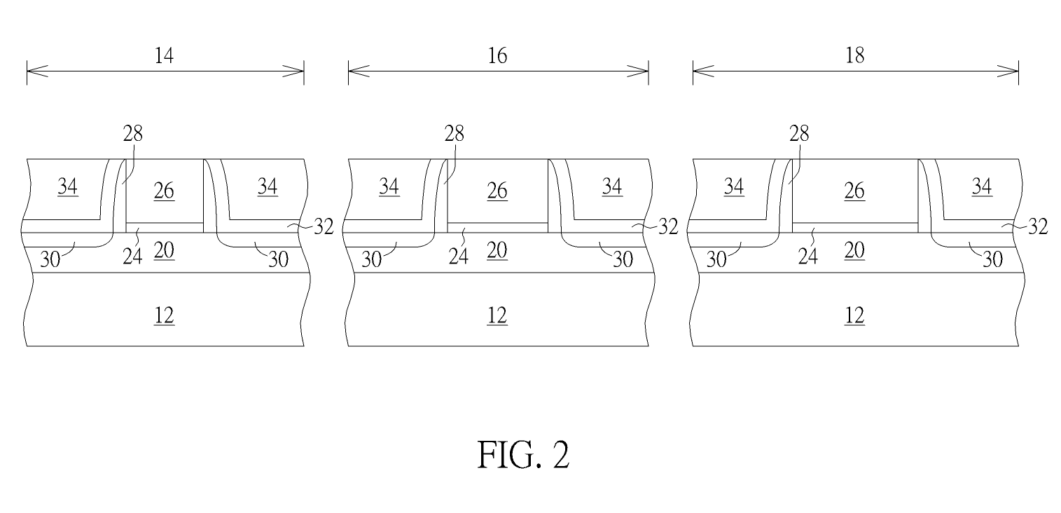

Next, as shown in FIG. 2, a contact etch stop layer (CESL) 32 composed of silicon nitride could be selectively formed on the substrate 12 to cover the dummy gates 22, and an interlayer dielectric layer 34 is formed on the CESL 32. Next, a planarizing process, such as chemical mechanical polishing (CMP) process is conducted to remove part of the ILD layer 34 and part of the CESL 32 to expose the gate material layer 26 composed of polysilicon, in which the top surface of the gate material layer 26 on each of the regions 14, 16, 18 and the top surface of the ILD layer 34 are coplanar.

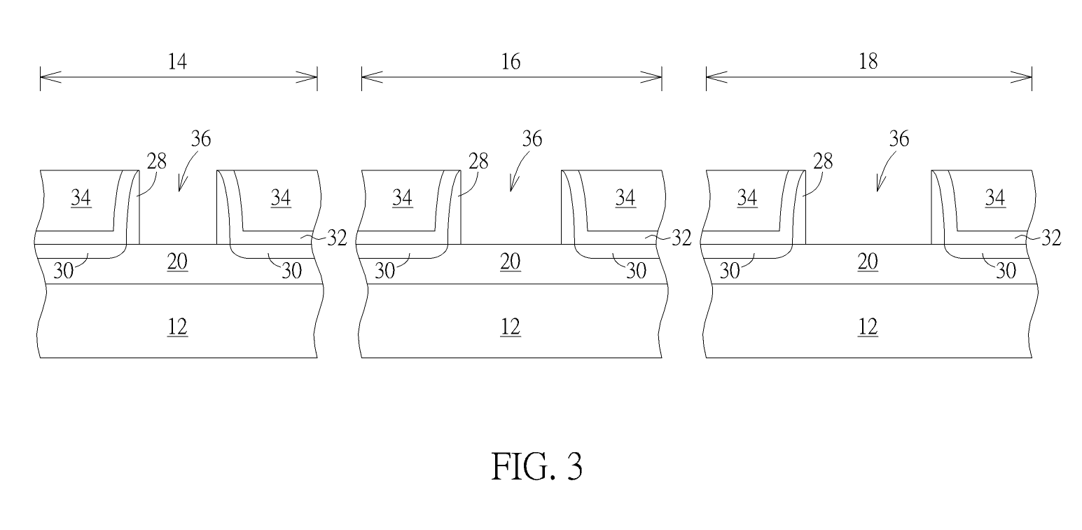

Next, a replacement metal gate (RMG) process is conducted to transform the dummy gates 22 into metal gates. For instance, as shown in FIG. 3, a selective dry etching or wet etching process could be conducted by using etchant including ammonium hydroxide (NH₄OH) or tetramethylammonium hydroxide (TMAH) to remove the dummy gates 22 or the gate material layer 26 in the gate structures for forming recesses 36 in the ILD layer 34.

It should be noted that since the dummy gates 22 on the substrate 12 preferably have different size, the recesses 36 formed after removing the dummy gates 22 would also have different size. In this embodiment, the recess 36 on region 14 preferably has the smallest size, the recess 36 on region 16 preferably has medium size or slightly larger than the recess 36 on region 14, and the recess 36 on region 18 preferably has the largest size of the three. Similar to the statement regarding the term “size” used in this embodiment made above, the recesses 36 having different size specifically refers to that the recess 36 on each of the regions 14, 16, 18 preferably has different width and/or length while other parameters such as depth of the recesses 36 are the same.

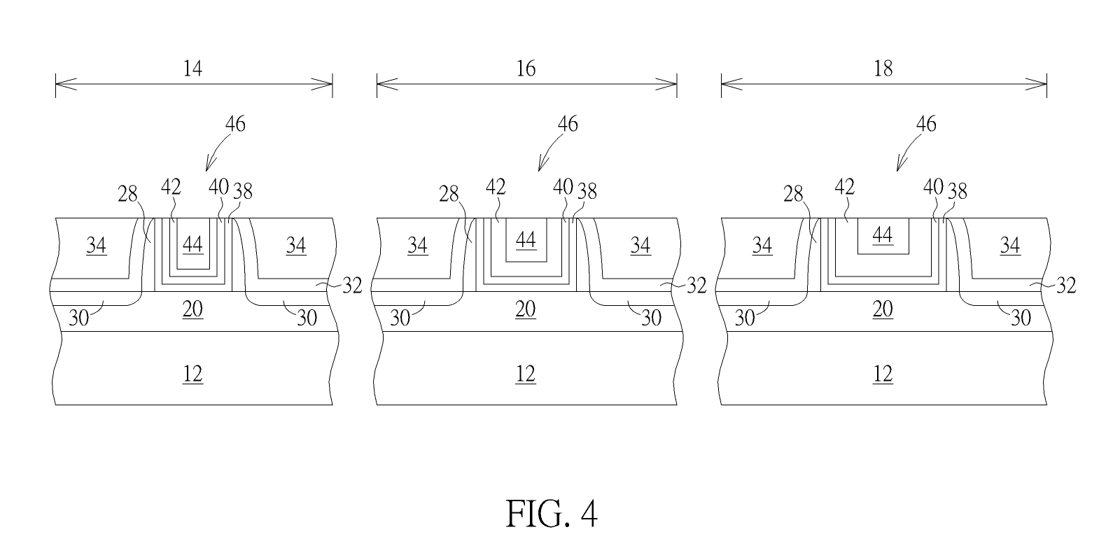

Next, as shown in FIG. 4, a high-k dielectric layer 38, a bottom barrier metal (BBM) layer 40, a work function metal layer 42, and a low resistance metal layer 44 are sequentially formed in the recesses 36, and a planarizing process, such as CMP is conducted to remove part of the low resistance metal layer 44, part of the work function metal layer 42, part of the BBM layer 40, and part of the high-k dielectric layer 38 to form metal gates 46 on the regions 14, 16, 18.

In this embodiment, since the recesses 36 on the regions 14, 16, 18 already have different size before the material layers are deposited, the high-k dielectric layer 38, BBM layer 38, and/or work function metal layer 42 could also have different thickness as soon as they are deposited.

More specifically, the high-k dielectric layer 38 on the regions 14, 16, 18 could have different thickness, the BBM layer 40 on the regions 14, 16, 18 could have different thickness, and/or the work function metal layer 42 on the regions 14, 16, 18 could have different thickness. For instance, it would be desirable to have only the high-k dielectric layer 38 on the regions 14 and 16 to have different thickness, only the high-k dielectric layer 38 on the regions 16 and 18 to have different thickness, only the high-k dielectric layer 38 on regions 14 and 18 to have different thickness, or all the high-k dielectric layer 38 on the regions 14, 16, 18 to have different thickness. Similarly, it would be desirable to have only the BBM layer 40 on regions 14 and 16 to have different thickness, only the BBM layer 40 on regions 16 and 18 to have different thickness, only the BBM layer 40 on regions 14 and 18 to have different thickness, or all the BBM layer 40 on regions 14, 16, 18 to have different thickness. Moreover, it would be desirable to have only the work function metal layer 42 on region 14 and 16 to have different thickness, only the work function metal layer 42 on regions 16 and 18 to have different thickness, only the work function metal layer 42 on regions 14 and 18 to have different thickness, or all the work function metal layer 42 on regions 14, 16, 18 to have different thickness.

It should be noted that even though the thickness of each of the high-k dielectric layer 38, BBM layer 40, and work function metal layer 42 on regions 14, 16, 18 could all be different, the present invention preferably forms high-k dielectric layer 38 having the same thickness on regions 14, 16, 18, BBM layer 40 having the same thickness on regions 14, 16, 18, and work function metal layers 42 having different thickness on regions 14, 16, 18, as shown in FIG. 4. However, according to another embodiment of the present invention, it would also be desirable to form high-k dielectric layer 38 having same thickness on regions 14, 16, 18 and BBM layer 40 having different thickness on regions 14, 16, 18 while the thickness of work function metal layer 42 could either be the same or different on regions 14, 16, 18.

In this embodiment, the formation of work function metal layer 42 on regions 14, 16, 18 could not only be accomplished by directly depositing into the recesses 36 having different sizes, but also by depositing a work function metal layer into the recesses 36 and then removing part of the work function metal layer on particular region to adjust the overall thickness of the work function metal layer. For instance, it would be desirable to first deposit a work function metal layer into the recess 36 on the regions 14, 16, 18, then form a patterned mask (such as a patterned resist) on region 18, and then remove part of the work function metal layer on regions 14 and 16 not covered by the patterned resist, so that the overall thickness of work function metal layer on region 18 is greater than the thickness of work function metal layer on regions 14 and 16. Next, another patterned resist could be formed on regions 16 and 18, and another etching process could be conducted to remove part of the work function metal layer on region 14. This produces a work function metal layer having three different kinds of thickness, in which the thickness of work function metal layer on region 18 is greater than the thickness of work function metal layer on region 16 while the thickness of work function metal layer on region 16 is also greater than the thickness of work function metal layer on region 14.

In this embodiment, the high-k dielectric layer 38 is preferably selected from dielectric materials having dielectric constant (k value) larger than 4. For instance, the high-k dielectric layer 38 may be selected from hafnium oxide (HfO₂) , hafnium silicon oxide (HfSiO₄) , hafnium silicon oxynitride (HfSiON) , aluminum oxide (Al₂O₃) , lanthanum oxide (La₂O₃) , tantalum oxide (Ta₂O₅) , yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT) , lead zirconate titanate (PbZrₓTi₁₋ₓO₃, PZT), barium strontium titanate (BaₓSr₁₋ₓTiO₃, BST) or a combination thereof.

Preferably, the BBM layer 40 is selected from the group consisting of TiN and TaN, but not limited thereto.

In this embodiment, the work function metal layer 42 is formed for tuning the work function of the later formed metal gates to be appropriate in an NMOS or a PMOS. For an NMOS transistor, the work function metal layer 42 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 42 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 42 and the low resistance metal layer 44, in which the material of the barrier layer may include titanium (Ti), titanium nitride (TiN), tantalum (Ta) or tantalum nitride (TaN). Furthermore, the material of the low-resistance metal layer 44 may include copper (Cu), aluminum (Al), titanium aluminum (TiAl), cobalt tungsten phosphide (CoWP) or any combination thereof. Since the process of using RMG process to transform dummy gate into metal gate is well known to those skilled in the art, the details of which are not explained herein for the sake of brevity.

Next, part of the high-k dielectric layer 38, part of the BBM layer 40, part of the work function metal layer 42, and part of the low resistance metal layer 44 could be removed to form a recess (not shown), and a hard mask (not shown) could be formed in the recess so that the top surfaces of the hard mask and ILD layer 34 are coplanar. The hard mask could be selected from the group consisting of silicon oxide, silicon nitride, silicon oxynitride, and silicon carbon nitride.

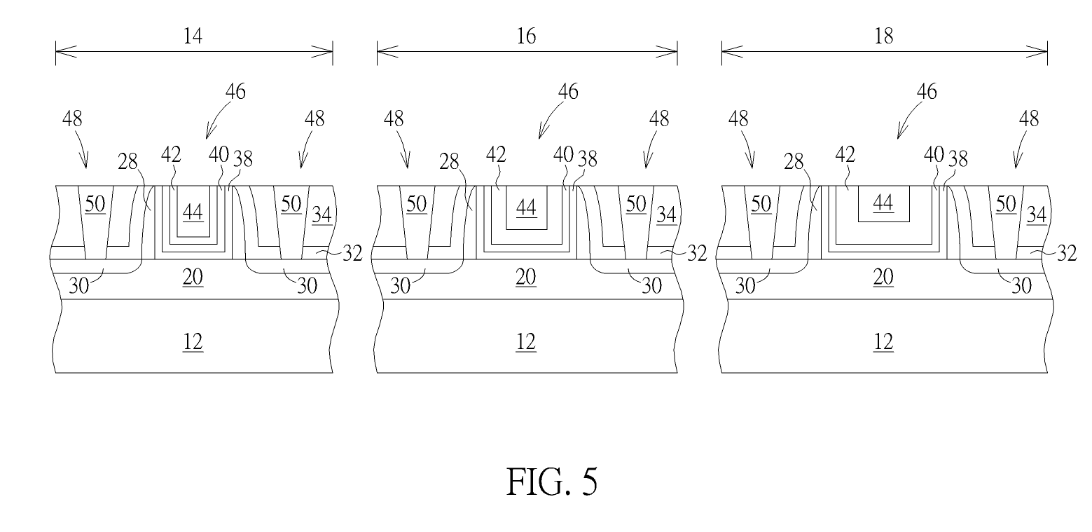

Next, as shown in FIG. 5, a contact plug formation could be conducted to form contact plugs 48 electrically connected to the source/drain regions 30. In this embodiment, the formation of contact plugs 48 could be accomplished by removing part of the ILD layer 34 and part of the CESL 32 to form contact holes (not shown), and then depositing a barrier layer (not shown) and a metal layer 50 into the contact holes. A planarizing process, such as CMP is then conducted to remove part of the metal layer 50, part of the barrier layer, and even part of the ILD layer 34 to form contact plugs 48, in which the top surface of the contact plugs 48 is even with the top surface of the ILD layer 34. In this embodiment, the barrier layer is selected from the group consisting of Ti, Ta, TiN, TaN, and WN, and the metal layer 50 is selected from the group consisting of Al, Ti, Ta, W, Nb, Mo, and Cu.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
providing a substrate; and
forming a first metal gate and a second metal gate on the substrate, wherein the first metal gate comprises a first work function metal layer, the second metal gate comprises a second work function metal layer, the first metal gate and the second metal gate comprise different size, and the first work function metal layer and the second work function metal layer comprise different thickness.

2. The method of claim 1, further comprising:
forming a first dummy gate and a second dummy gate on the substrate;
forming a dielectric layer on the first dummy gate and the second dummy gate;
planarizing the dielectric layer;
removing the first dummy gate and the second dummy gate to form a first recess and a second recess.

3. The method of claim 2, wherein the first dummy gate and the second dummy gate comprise different size.

4. The method of claim 2, further comprising:
forming the first work function metal layer in the first recess and the second work function metal layer in the second recess;
forming a first low resistance metal layer on the first work function metal layer and a second low resistance metal layer on the second work function metal layer; and
planarizing the first low resistance metal layer, the first work function metal layer, the second low resistance metal layer, and the second work function metal layer to form the first metal gate and the second metal gate.

5. The method of claim 1, wherein the first work function metal layer and the second work function metal layer comprise the same conductive type.

6. The method of claim 4, further comprising forming the first recess, the second recess, and a third recess in the dielectric layer, wherein the first recess, the second recess, and the third recess comprise different size.

7. The method of claim 6, further comprising:
forming the first dummy gate, the second dummy gate, and a third dummy gate on the substrate;
forming the dielectric layer on the first dummy gate, the second dummy gate, and the third dummy gate;
planarizing the dielectric layer;
removing the first dummy gate, the second dummy gate, and the third dummy gate to form the first recess, the second recess, and the third recess.

8. The method of claim 7, wherein the first dummy gate, the second dummy gate, and the third dummy gate comprise different size.

9. The method of claim 7, further comprising forming a third work function metal layer in the third recess, wherein the first work function metal layer, the second work function metal layer, and the third work function metal layer comprise different thickness.

10. The method of claim 9, further comprising:
forming the first low resistance metal layer on the first work function metal layer, the second low resistance metal layer on the second work function metal layer, and a third low resistance metal layer on the third work function metal layer; and
planarizing the first low resistance metal layer, the first work function metal layer, the second low resistance metal layer, the second work function metal layer, the third low resistance metal layer, and the third work function metal layer to form the first metal gate, the second metal gate, and a third metal gate.

11. The method of claim 9, wherein the first work function metal layer, the second work function metal layer, and the third work function metal layer comprise same conductive type.

12. A semiconductor device, comprising:
a substrate;
a first metal gate on the substrate, wherein the first metal gate comprises a first work function metal layer; and
a second metal gate on the substrate, wherein the second metal gate comprises a second work function metal layer, the first metal gate and the second metal gate comprise different size, and the first work function metal layer and the second work function metal layer are U-shaped and comprise different thickness.

13. The semiconductor device of claim 12, wherein the first work function metal layer and the second work function metal layer comprise the same conductive type.

14. The semiconductor device of claim 12, further comprising a dielectric layer on the substrate and around the first metal gate and the second metal gate, wherein the top surfaces of the first metal gate, the second metal gate, and the dielectric layer are coplanar.

15. The semiconductor device of claim 12, further comprising a third metal gate on the substrate, wherein the third metal gate comprises a third work function metal layer, the first metal gate, the second metal gate, and the third metal gate comprise different size, and the first work function metal layer, the second work function metal layer, and the third work function metal layer comprise different thickness.

16. The semiconductor device of claim 12, further comprising a dielectric layer on the substrate and around the first metal gate, the second metal gate, and the third metal gate, wherein the top surfaces of the first metal gate, the second metal gate, the third metal gate, and the dielectric layer are coplanar.
